(19) United States
(12) Patent Application Publication
(10) Pub. No.: US 2014/0106095 A1
(43) Pub. Date: Apr. 17, 2014

(54) ANODIC BONDING FOR A MEMS DEVICE

(71) Applicant: Francois Bianchi, Martigny (CH)

(72) Inventor: Francois Bianchi, Martigny (CH)

(73) Assignee: DEBIOTECH S.A., Lausanne (CH)

(21) Appl. No.: 14/124,946

(22) PCT Filed: Jun. 7, 2012
(86) PCT No.: PCT/IB2012/052868

§ 371 Date: Dec. 9, 2013

(30) Foreign Application Priority Data
Jun. 8, 2011 (EP) 11169070.7

(51) Int. Cl. B81C 3/00; B81B 1/00

(52) U.S. Cl. CPC B81C 3/001; B81B 1/00
USPC 428/34.6; 156/274.4

(57) ABSTRACT

The invention relates to a device comprising a wafer comprising a silicon area and a wafer comprising a glass area fastened to each other, the fastening zone thus formed between the wafers defining a multilayer structure comprising a first layer protecting the silicon from physical changes caused by attack of the surface, which layer covers the silicon area, and a second layer protecting the glass from physical changes caused by attack of the surface, which layer covers the glass area; said multilayer structure furthermore comprising at least one additional layer enabling anodic bonding between the two protective layers; said device containing at least one fluid channel protected by said protective layers and able to contain a solution temporarily.

### FIELD OF THE INVENTION

The present invention relates to the field of electromechanical microsystems commonly referred to as micro electro mechanical systems (MEMS) type devices. More particularly, it relates to the anodic bonding between a wafer of which one surface is made from silicon and a wafer of which one surface is made from glass. These two elements constitute the basic components of most MEMS type devices, a microsystem comprising one or more mechanical elements that are able to use electricity as an energy source if necessary in order to perform a function as a sensor and/or actuator with at least one structure having dimensions in the micrometric range, the function of the system being assured in part by the shape of said structure.

### ABBREVIATIONS USED IN THE PRESENT TEXT

ALD Atomic Layer Deposition

CVD Chemical Vapour Deposition

LPCVD Low Pressure Chemical Vapour Deposition

MEMS Micro Electro Mechanical Systems

MIP Micro Implantable Pump

PECVD Plasma Enhanced Chemical Vapour Deposition

PVD Physical Vapour Deposition

a-Si Amorphous silicon

### STATE OF THE ART

A microfluidic system such as a pump or flow regulator must be protected against chemical attack, particularly if it is intended to be implanted in a patient for many years, such as a system for releasing an active ingredient.

Generally, elements that are sensitive to such chemical attack, such as silicon or glass wafers, are covered with a protective layer. It is not always a simple matter to assemble these elements together. Such an assembly process was the object of a patent application relating to an implantable micro-fluidic system [R11].

For many years, several research groups have been conducting research (successfully) [R1, R4] into the possibility of bonding a surface of silicon coated in silicon nitride to a glass surface (generally Pyrex 7740).

In addition, other research groups have shown that it is possible to join two wafers of the same kind (made from silicon [R6, R7] or glass [R2, R5]) by anodic bonding using intermediate layers. But as is stated in the article by Knowles [R3], the objective in these studies was to enable bonding between two substrates that were impossible or difficult to join a priori, without recourse to one or more intermediate layers.

Another approach uses a direct bonding technique (without the aid of electrical voltage but using pressure and surface preparation) to join a silicon wafer coated with silicon nitride to a glass wafer [R8].

### GENERAL DESCRIPTION OF THE INVENTION

The present invention consists of a MEMS type device comprising a wafer such as is defined in the claims.

Said protection layers preferably serve to protect said wafers from attacks on the surface, which may be for example chemical, electrochemical, physical and/or mechanical in nature. In particular, such an attack may be associated with the pH of a contact solution or with a dissolution effect of the wafer cause by a solution.

Unlike the teaching of the prior art [R11], which simply presents the design of a fluidic resistance for an implantable pump in the form of a capillary network with a layer that offers better pH protection than that of glass or silicon, the problem addressed by our invention relates to the packaging of a MEMS by conventional anodic bonding of a wafer having one surface made of silicon with a wafer having one surface made of glass—a hard material or alloy most often made of silicon oxide (SiO₂ silica, the principle component of sand) and fluxes, while protecting one another from chemical attacks of the surface. In this case, borosilicate such as Pyrex 7740 or an equivalent material such as those described in Table 1 (see below) will be used for preference, since a possible objective is to gain the benefit of the transparency of this material.

Table 1 Examples of commercially available glasses and glass-ceramic used for anodic bonding

| Manufacturer | Code |
|---|---|
| Corning | No. 0080 |
| | No. 0120 |
| | No. 1720 |
| | No. 1729 |
| | No. 1737 |
| | No. 7052 |
| | No. 7056 |
| | No. 7059 |
| | No. 7070 |
| | No. 7740 (Pyrex) |
| | No. 9626 |
| | No. 9741 |
| | Zerodur |
| Hoya | Glass ceramic |
| Matsunami | SD-2 |
| Schott | No. 0700 |
| | Borofloat |
| | Forturan |
| | No. 8239 |
| | No. 8330 (Tempax) |

To achieve this protection from attacks on the surface, silicon may be protected by a thin layer of type Si₃N₄ or TiN (already described in the literature), or in a more sophisticated manner by a combination of two layers: TiO₂+Si₃N₄, or TiO₂+a-Si. In this case, the layer of a-Si or Si₃N₄ that is deposited on the protection layer is not intended to protect the device against attacks on the surface, but merely to make the bond possible. This is also true for all the layer combinations described in Table 2.

Table 2 Examples of various materials used as interlayer material in conjunction with anodic bonding

| Bond type | Interlayer material |
|---|---|
| Si-Glass | Al |
| | Al/Ti |
| | Hf |
| | Mg |
| | Schott no. 8329 glass |
| | Si (amorphous) |
| | Si (polycrystalline) |
| | SiC (sputtered) |
| | Si₃N₄ |
| | SiNₓ |
| | SiO₂ (dry and wet thermally grown) |
| | SiO₂ (sputtered) |
| | Sn |
| Si—Si | Iwaki no. 7570 glass (sputtered) |
| | Lithium glass (sputtered) |
| | Pyrex-like glasses (sputtered or evaporated) |
| | Pyrex-like glasses with Al, Poly-Si, Si₃N₄, SiO₂ |
| | SiO₂ (dry and wet thermally grown) |
| | SiO₂ (sputtered) |
| Glass-Glass | Al |
| | ITO/a-Si |
| | Ni—Cr |
| | Poly-Si, Si₃N₄, SiC, a-Si |

The particular feature of Si₃N₄ is that it can function both as a protection layer and as an anodic bonding layer. However, it is difficult to make conformal deposits with Si₃N₄, particularly on structured surfaces. Yet surfaces of this kind are essential to the effectiveness of such layers as protection. In fact, the slightest defect can become the weak point in the system, which will be most vulnerable to the chemical attacks. It is therefore preferable to use TiO₂ as a protective material, which is easy to deposit conformally on a structured surface as it is compatible with techniques such as ALD. Si₂N₄, which is not compatible with ALD type conformal depositing methods, may be deposited on top of the TiO₂, on the bonding zone to make anodic bonding possible. It is known from the literature that it is not possible to achieve anodic bonding directly on titanium oxide deposited on silicon.

In the present document, a conformal deposit is defined as a layer deposited on a surface having a very high aspect ratio (such as depressions) that mould homogenously to said surface.

If the glass is chemically inert with respect to a solution of basic pH, the solubility of silicon oxide, an essential component of glass, increases significantly with the pH, as shown in FIG. 1. Therefore, the deterioration of a glass structure exposed to basic pH solutions over the long term is a risk that is addressed with this invention. Thus, like the silicon, the glass must be protected by a layer that is capable of withstanding a basic pH attack.

Whereas silicon nitride or titanium oxide lend themselves very well to being deposited on the glass as a protective layer, on the other hand it is not possible to effect direct anodic bonding between one of these protected wafers and a silicon surface which itself has a protective layer. We do not know of any protective layer that can be applied to a glass wafer and is also directly compatible with anodic bonding. In the case of glass, for example, silicon nitride or titanium oxide will be used as the protective layer, which can be combined with a thin layer of silicon oxide as the bonding layer.

This bonding layer must not only enable anodic bonding to take place, but also serve to preserve said bond over time despite being exposed to a basic pH solution. The bonding layer must be thin enough to allow the creation of capillary forces that are strong enough to create a valve-type capillary stop, preventing the basic solution from infiltrating the bonding zone and thus avoiding the risks of delamination. Since anodic bonding induces a chemical change in the material in the bonding zone by creating covalent bonds, the result of said chemical transformation may change the chemical/physical properties of the material and render it more resistant to basic solutions than was the native form thereof before anodic bonding.

Capillary valves or capillary stop valves serve to stop the flow of a solution inside a microfluidic device using a capillary pressure barrier when the geometry of the channel changes suddenly.

FIG. 2 shows an example of a complex structure that can be protected and bonded using the suggested technique. The following elements are present in said structure:

1. Borosilicate glass (for example, Pyrex 7740)

2. Functional surface layer

3. Protective layer (TiO₂ for example)

4. Protective layer (SiO₂ for example)

5. Monocrystalline silicon

6. Protective layer (TiO₂ for example)

7. Protective layer (Si₃N₄ for example)

Despite the presence of intermediate layers, it is still possible to use conventional anodic bonding parameters.

In order to reduce the risk of local defects (pinholes), it is possible to we can use a conformal depositing technique called Atomic Layer Deposition (ALD), which is considered not to create pinholes or, if depositing by Chemical Vapour Deposition (CVD), to carry out the deposit in multiple steps.

When a process to obtain conformal deposit is used, it is usually impossible to carry out bonding between the two wafers. However, the present invention makes it possible to bond two wafers, of which at least one is furnished with a conformal deposit.

Moreover, the device of the present invention is obtained by applying a layer for protection from an attack on the surface over at least one zone made of silicon and a layer for protection from an attack on the surface over at least a zone made of glass. The wafers of the device may be structured before or after said protective layers are applied. After the application of these protective layers, a material that enables the anodic bonding to take place is added in a thin layer between the two protective layers.

The unit that makes up a device is able to comprise at least one fluid path. Said fluid path enables a solution to circulate not only between the protective layers but also to pass through all or part of said wafers. It may consist of channels, a valve, a sensor, pumping means, and so on.

Besides enabling said protective layers to be bonded to one another, due to its thickness, said bonding layer prevents said solution from infiltrating the bonding zone that defines the lateral extremities of said fluid path, through which said solution passes.

These layers may be applied conformal using various techniques: by deposition (ADL, LPCVD, and so on) or by growths (dry and wet oxidations).

The wafers structured and protected in this way are assembled with each other in order to create a fluid path.

### LIST OF FIGURES

FIG. 1: Solubility curve of silica and quartz as a function of pH.

FIG. 2: Cross sectional view of a complex structure protected from chemical attack by thin layers and sealed by conventional anodic bonding.

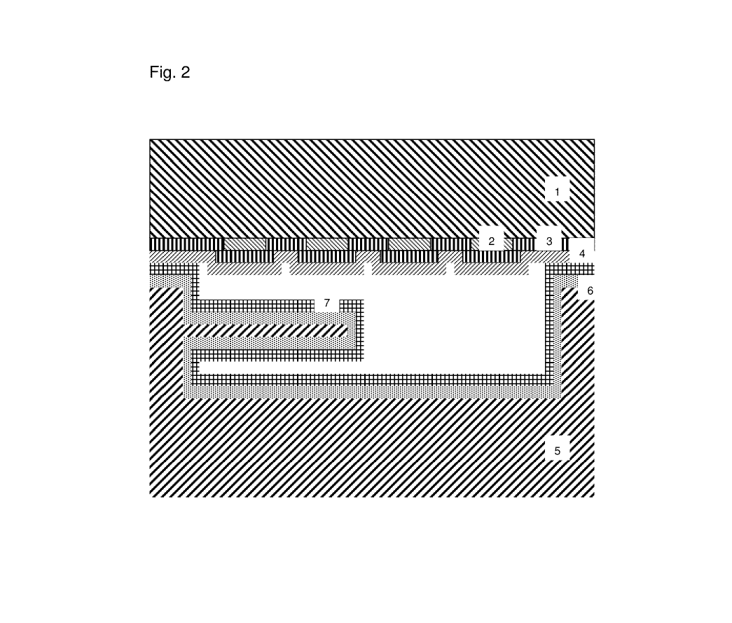

FIG. 3: Test vehicle used to detect the characteristics of the protective layers. It consists of two fluid inlets (the 2 circles) and a serpentine channel constituting a fluid resistance.

FIG. 4: Schematic of the channel constituting the fluid resistance with various protective layers used. Layers (c) and (b) are deposited on the Pyrex, and layers (a) and (d) are deposited on the silicon. Layer (a) is preferably Si₃N₄ and can be bonded directly to the Pyrex or to layer (c), which is the bonding layer that is deposited on protective layer (b), which serves to protect the Pyrex. Layer (d) is a protective layer deposited on the silicon and which can be deposited by ALD but which cannot be bonded directly with the Pyrex or layer (c). Consequently, it may be added to layer (d), layer (a) which in this instance enables bonding of a silicon wafer that has a protective layer which cannot be bonded with a Pyrex wafer, whether the Pyrex wafer is protected or not.

FIG. 5: SEM image of the cross section of the fluid path which has been exposed to a solution with pH 12 for 8 days and which does not have a protective coating or bond. The fluid resistance of this has been reduced by due to etching of the silicon, this value is used as a control with regard to the other channels that have undergone treatment with a protective coating. The nominal depth of the channel is 16 μm.

FIG. 6: Fluid resistance progression depending on the length of exposure for a channel having a protective layer of 50 nm Si₃N₄ deposited on the silicon wafer. The breaking threshold determined relative to the control corresponds to a decrease in fluid resistance by a factor of 2.

FIG. 7: SEM image of the cross section of the fluid path which has been exposed to a solution with pH 12 for 28 days and which has a protective layer of 50 nm Si₃N₄ deposited on the silicon. Anisotropic attack may be seen clearly at the intersection of the channels that form the serpentine, whereas the bottom of the channels is protected by Si₃N₄ and is not attacked. The observed defect suggests that a thickness of 50 nm does not offer adequate protection of the bond.

FIG. 8: Fluid resistance progression depending on the length of exposure for a channel having a protective layer of 100 nm Si₃N₄ deposited on the silicon wafer. The breaking threshold determined relative to the control corresponds to a decrease in fluid resistance by a factor of 2.

FIG. 9: SEM image of the cross section of the fluid path which has been exposed to a solution with pH 12 for 48 days, and which has a protective layer of 100 nm Si₃N₄ deposited on the silicon. A pH attack may be seen clearly at the interface of the wafers defining the channels that constitute the serpentine fluid resistance, thus creating a short circuit between two channels that make up the serpentine. On the other hand, no anisotropic attack of the Si is observed, which shows that the thickness of 100 nm is sufficient to ensure adequate protection of the bond. An increase of 2 μm in the channel depth suggests that the Pyrex has been eroded, leading to reduced flow resistance.

FIG. 10: Fluid resistance progression depending on the length of exposure for a channel having a protective layer of 200 nm Si₃N₄ deposited on the silicon wafer. The breaking threshold determined relative to the control corresponds to a decrease in fluid resistance by a factor of 2.

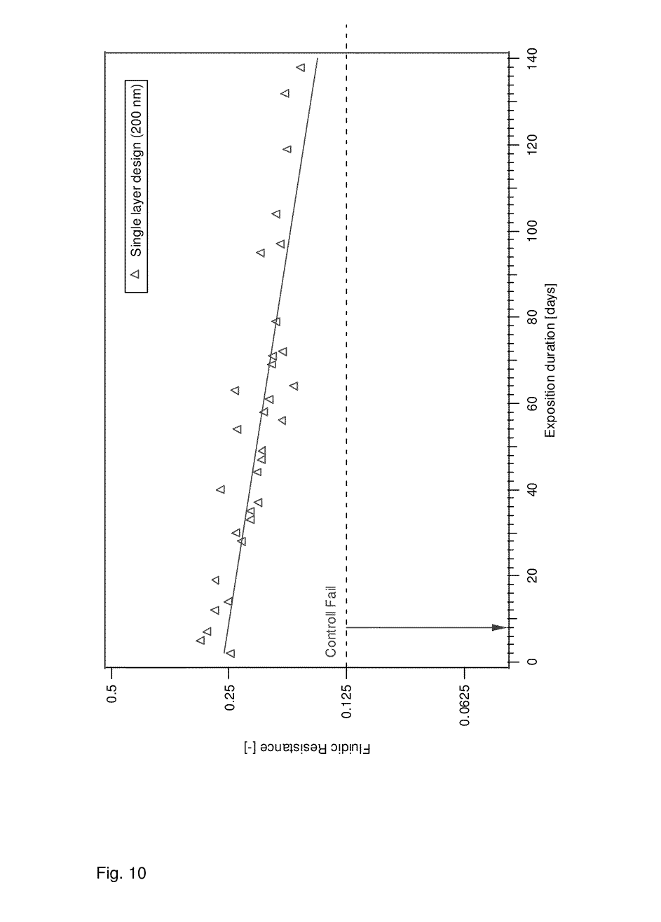

FIG. 11: SEM image of the cross section of the fluid path which has been exposed to a solution with pH 12 for 140 days, and which has a protective layer of 100 nm Si₃N₄ deposited on the silicon. A pH attack may be seen clearly at the interface of the wafers defining the channels that constitute the serpentine fluid resistance, and an increase of more than 6 μm in the depth of the channel caused by a chemical attack on the Pyrex. The protected portion of the silicon does not seem to have been attacked. In this case, the distance between the channels that make up the serpentine is greater than 100 μm, preventing the creation of a short circuit between the channels and an excessively large drop in fluid resistance, such as is the case in FIG. 9.

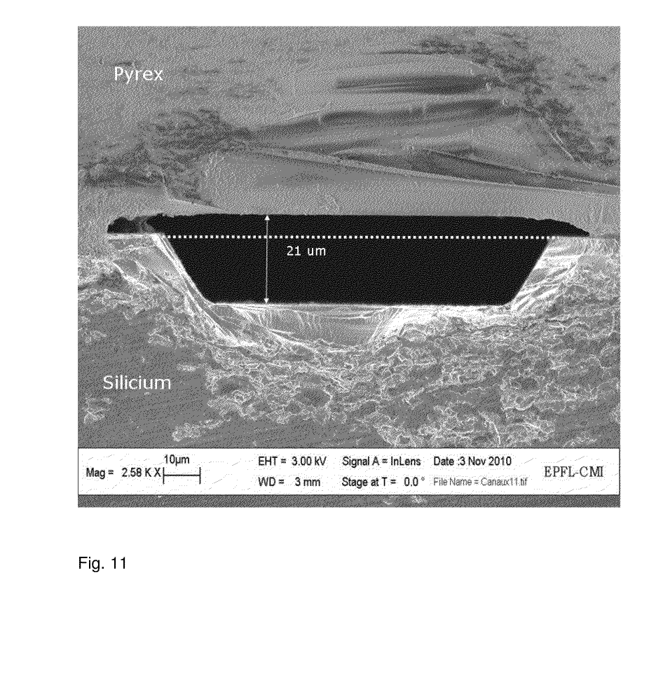

FIG. 12: Fluid resistance progression depending on the length of exposure for a channel having a protective layer of 100 nm Si₃N₄ deposited on the silicon, a protective layer of 200 nm TiO₂ on the Pyrex and a layer of 100 nm SiO₂ deposited on the TiO₂ layer, permitting anodic bonding. The breaking threshold determined relative to the control corresponds to a decrease in fluid resistance by a factor of 2.

FIG. 13: SEM image of the cross section of the fluid path which has been exposed to a solution with pH 12 for 140 days, and which has a protective layer of 100 nm Si₃N₄ deposited on the silicon, a protective layer of 200 nm TiO₂ on the Pyrex and a layer of 100 nm SiO₂ deposited on the TiO₂ layer, permitting anodic bonding. It may be seen very clearly that the channel has kept its nominal depth. It is also shown that the protective layers and the bonding layer have fulfilled their functions perfectly.

### DETAILED DESCRIPTION OF THE INVENTION

While using an anodic bonding technique with standard parameters (350-400° C., 500-1000 V) it is possible to bond a silicon wafer to a wafer of glass (Pyrex 7740) despite the presence of intermediate layers that serve as protection from chemical attack.

Silicon can be protected by a thin (<50 nm) layer of TiN or any form of silicon nitride (deposited by ALD, PECVD, LPCVD) with variable stoichiometry. By using two layers it is also possible to protect it using a combination of TiO₂+Si₃N₄ or TiO₂+a-Si. With thicknesses of up to 250 nm for the TiO2, up to 500 nm for the additional layer of Si₃N₄ (this thickness may be as much as <1 μm for silicon nitride alone) or <500 nm for the additional layer of amorphous silicon.

The Pyrex may be protected by two layers: TiO₂ followed by SiO₂. Both layers may be deposited by ALD, reactive sputtering, PECVD (SiO₂), or LPCVD (SiO₂). The range of usable thicknesses is:
<500 nm for the SiO₂
<250 nm for the TiO₂

The use of ALD (Atomic Layer Deposition) as the deposition technique is very useful in our case since the number of topical defects (pinholes) is significantly lower than with the other deposition techniques mentioned [R9].

The use of ALD also makes it possible to conceive of protecting structures with extremely complex shapes because the technique is almost perfectly conformal (aspect ratio 1:1000 demonstrated [R10]).

In the case where the protection layers are deposited by CVD (Chemical Vapour Deposition), it is useful to proceed in several distinct stages. By shutting off the vacuum, this makes it possible to significantly reduce the risk of having two defects (pinholes) superimposed.

It should also be noted that this technique of anodic bonding does not require any pretreatment of the surfaces to prepare the bond. Unlike many other bonding techniques (polymer-bonding, plasma-activated bonding, and so on), as long as the wafers are free from particles larger than 0.5 μm it is easy to obtain a reliable and very tight bond.

Pressure tests on the different bonding configurations did not show any differences in the strength of the bond. It therefore seems that whatever the protective layers present on the Pyrex or silicon, anodic bonding is just as strong as in the case of a simple bond without a protective layer.

### EXPERIMENTAL RESULTS

I. Compatible Bond

Various experiments have demonstrated the difficulty of joining silicon and glass by anodic bonding in which intermediate layers are added. The nature of the materials, the thickness of layers, the order of deposition and the positions of the layers relative to the wafers are just a few of the key parameters that must be mastered to ensure reliable anodic bonding. In addition, the thickness of the bonding layer is a critical factor for achieving this function. For example, a thickness of more than 500 nm SiO₂ does not enable a bond to be made between the intermediate layers.

The following two examples illustrate three-layer bonding:

### EXAMPLE 1

Bonding tests were performed on a silicon—Pyrex assembly. A 100 nm layer of silicon nitride was deposited on the silicon. On the Pyrex side, a thin layer of TiO₂ (50 nm) covers the substrate. 100 nm SiO₂ was deposited on top of this assembly. The assembly was bonded at 380° C. with 750 V. Scalpel tests showed excellent adhesion.

### EXAMPLE 2

A silicon wafer was covered with a 100 nm layer of TiO₂ followed by a 200 nm layer of SiO₂ and then a further 100 nm layer of SiO₂. As before, the bond was completed at 380° C. and with 750 V was performed. The results of bonding also showed excellent adhesion between these two wafers.

Several phenomena are cited in the literature to explain anodic bonding. Below we compare our experimental results with these phenomena.

Firstly, oxidation at the interface is possible with oxygen from the Pyrex (particularly the NaOH dissociated by the electrical field). In our case, we found that this theory can possibly explain some of the results:
Silicon and/or Pyrex coated with TiO₂ probably does not bond because the TiO₂ prevents oxidation at the interface [R3]
Silicon nitride seems prevent bonding when deposited on Pyrex by blocking the passage of oxygen, but when deposited on the silicon it is possible to oxidise it and thus create the bond.
However, this explanation is not entirely satisfactory in the case of multi-layer bonds Si\TiO₂\Si₃N₄ with SiO₂\TiO₂\Pyrex that have been demonstrated. In fact, if the TiO₂ prevents the passage of oxygen from the Pyrex, why does bonding take place in this configuration? Does the SiO₂ layer deposited on the TiO₂ by PECVD release enough oxygen to enable bonding to take place? But in that case why does a thicker layer of SiO₂ prevent bonding?

The second phenomenon proposed by Veenstra R12 relates to the electrostatic force applied to the interface. Associated with the oxidation of the layers at the interface, the electrostatic force is a key to understanding: in our case, the titanium deposited on the Pyrex reduces the electrostatic force at the interface substantially.

A third phenomenon is the distance between the two wafers. This is why an electric field is applied to obtain an electrostatic force large enough to bring the wafers to be bonded into close contact with one another. In our case, the surface roughness, which is one of the aspects of proximity, might be significant: the difference in roughness between ALD deposits and sputtering is known, but does not seem to play an important part in our case.

II. Fluid Resistance

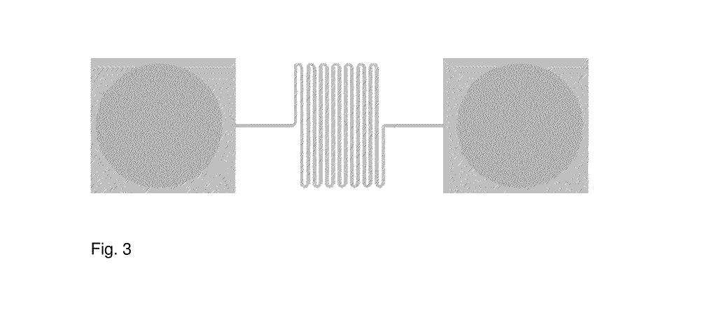

In order to show the quality of the protection and the bond under high pH conditions, a test vehicle representing a fluid resistance was used (FIG. 3). This served to reveal the deficiencies and capabilities of the various configurations used.

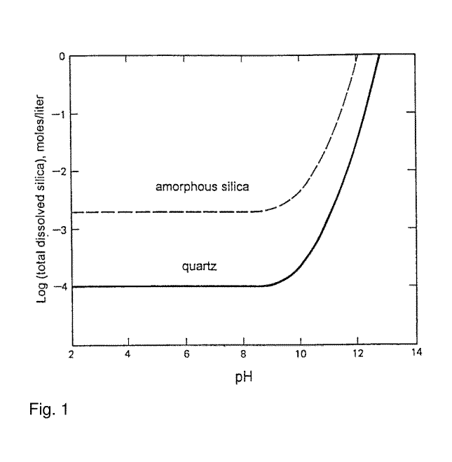

The test vehicle was exposed to a pH 12 solution, which represents an accelerated study form compared with a less basic pH in the context of chemical attack on silicon. In addition, regarding glass, FIG. 1 shows that the solubility of silicon dioxide increases exponentially above pH 9. Consequently, the results obtained at pH 12 represent an acceleration factor of at least 1000 compared with pH 9, and would correspond to a solution more representative of a drug injection system.

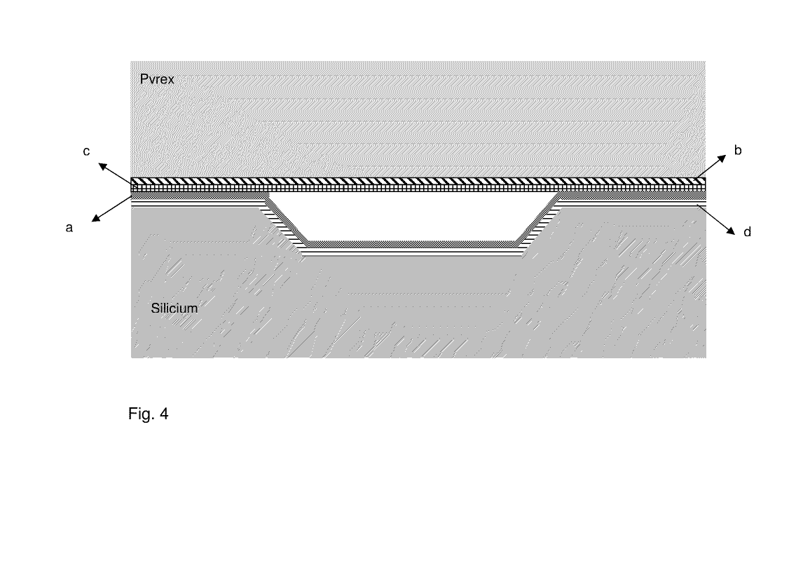

The channel in question may comprise 4 different layers (a), (b), (c) and (d), as shown in FIG. 4. Since no protective layer (b) applied to the Pyrex can be bonded directly to the silicon wafer (regardless of the configuration (a)-(d)), layer (b) must automatically be covered with a bonding layer (c). In the case of silicon, protective layer (d) can be bonded directly with the unprotected Pyrex or with bonding layer (c).

In the case in which the silicon is covered with a layer (d) that cannot be bonded, layer (a) may be deposited on protective layer (d) and be used as the bonding layer.

Depending on the type of materials used for the bonding layer, said layer may also be exposed to attack of the surface thereof by a solution passing through the fluid path. Moreover, a thickness of 200 nm ensures good anodic bonding of the two wafers, but with such a thickness the bond quickly begins to show weak points. Thus, a 200 nm layer of SiO₂ only partly prevents the basic solution from infiltrating the bond zone, which entails a considerable risk of delamination over time. In order to provide a liquid-tight joint between the two wafers, the applied layers of SiO₂ may have a thickness from 50 nm to 100 nm.

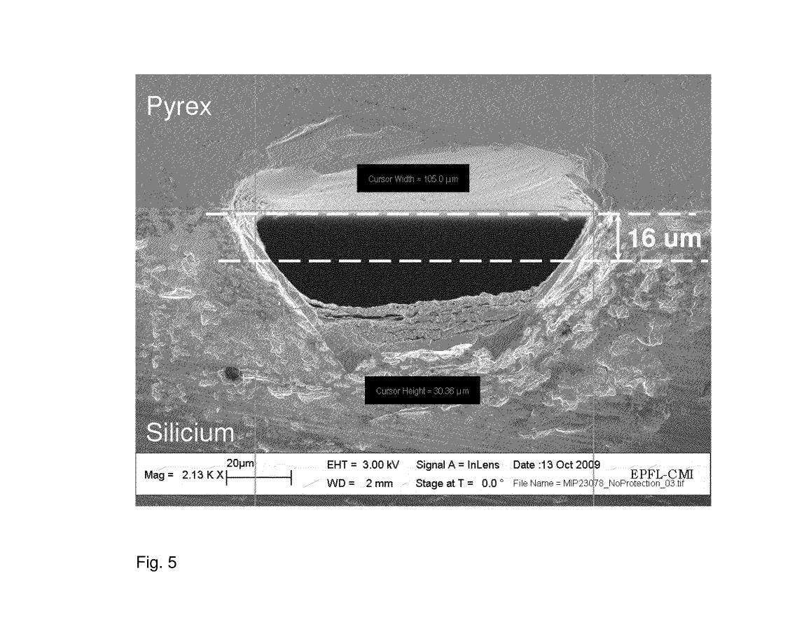

FIG. 5 shows the attack at pH 12 on a channel with no protection. The fluid resistance of this channel has decreased by a factor of 2, it is used as a control to determine the failure threshold for the channel designs with protective layers.

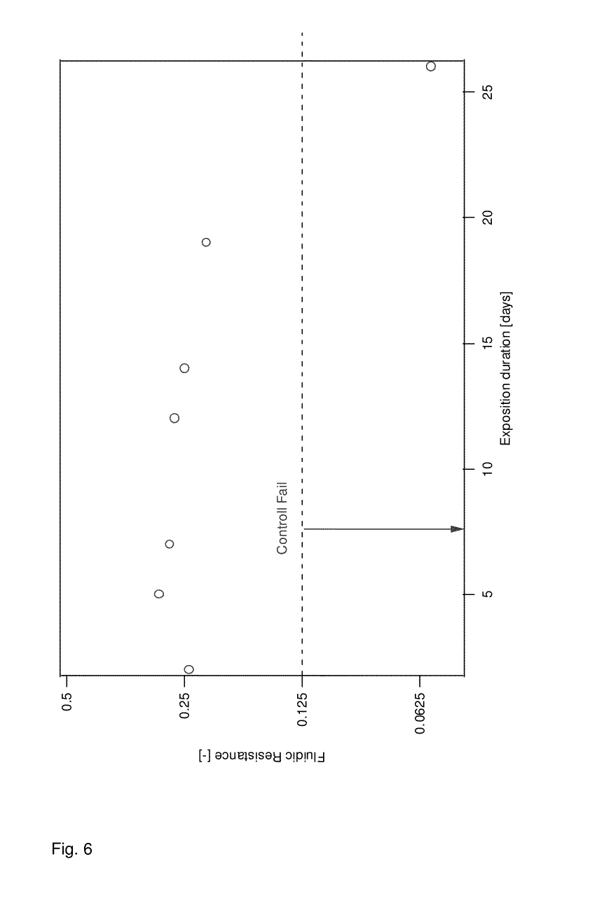

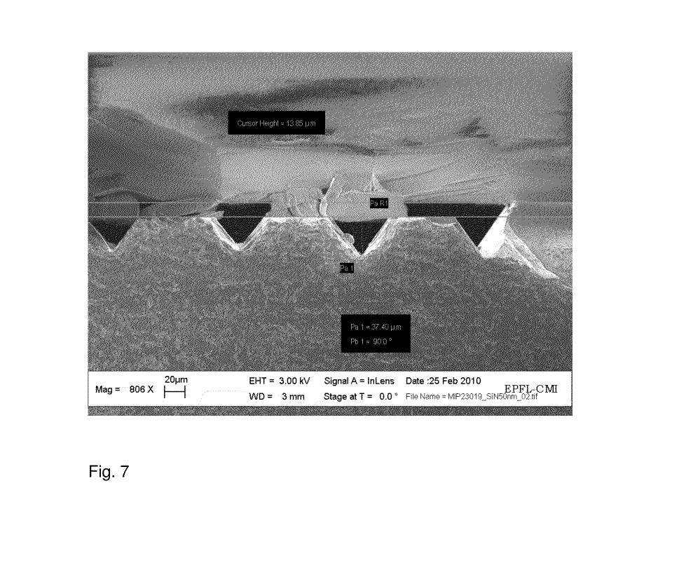

FIG. 6 shows a design comprising a single protective layer of 50 nm Si₃N₄ (a) in which the failure threshold was reached after 22 days. As shown in FIG. 7. the failure was caused by anisotropic etching between the channels, thus showing that the weakness is located at the bond. On the other hand, the protective layer on the bottom of the channel does not appear to have been damaged in comparison with the control of FIG. 5.

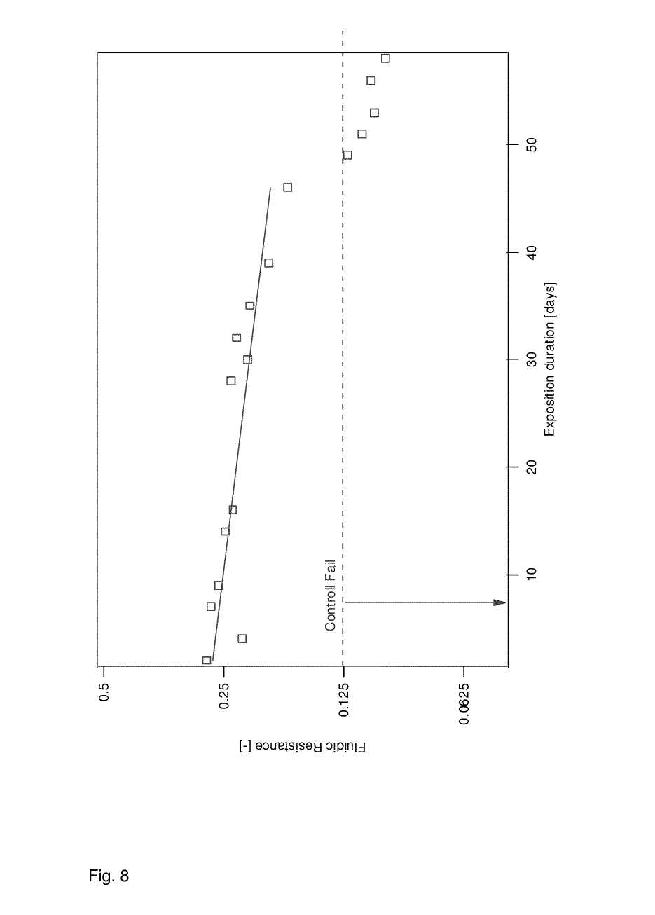

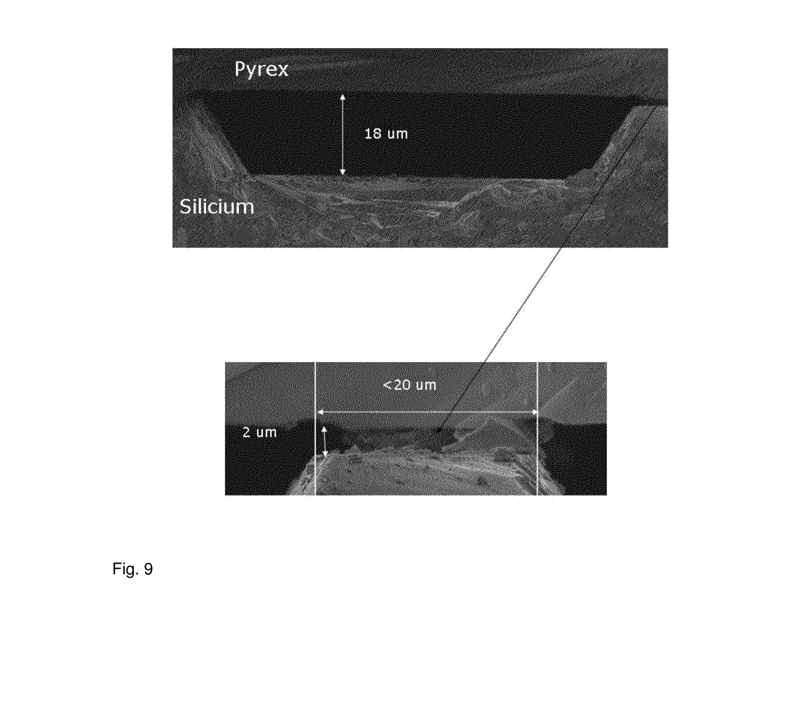

FIG. 8 shows a design comprising a single protective layer of 100 nm Si₃N₄ in which the failure threshold was reached after 48 days. As shown in FIG. 9, the failure was caused by the creation of a short circuit between the channels. The channel, whose depth increased by 2 microns, seems to have been exposed to attack from the side of the Pyrex wafer, while the side of the protected silicon wafer seems intact. This result suggests that a thickness of 100 nm is sufficient to ensure good performance characteristics of the layer designed to protect the bond on the side of the silicon wafer, unlike the bond previously tested with 50 nm Si₃N₄. The failure is probably the result of an attack on the unprotected Pyrex wafer.

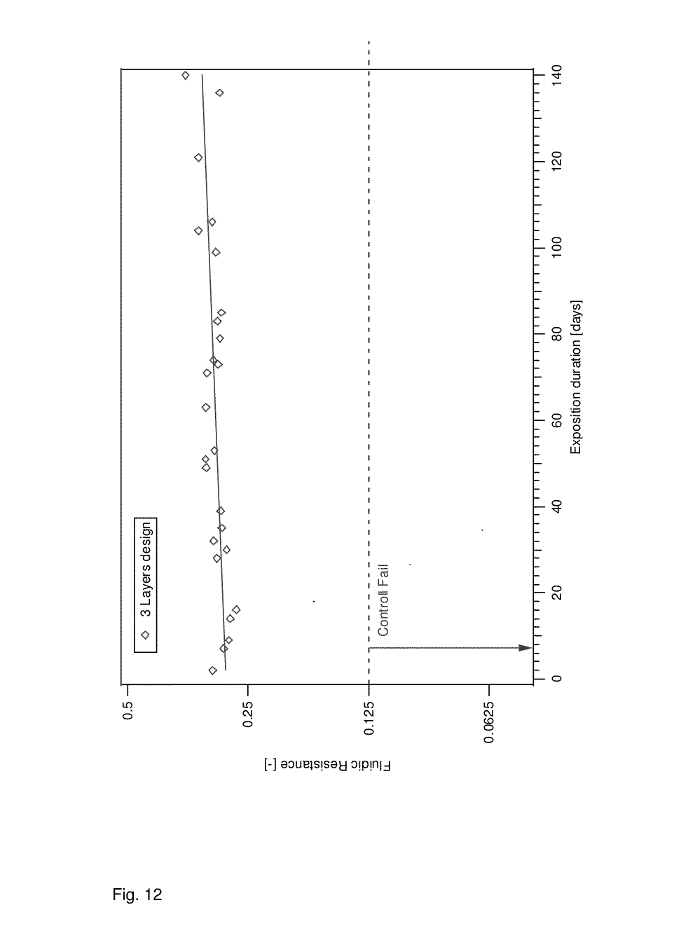

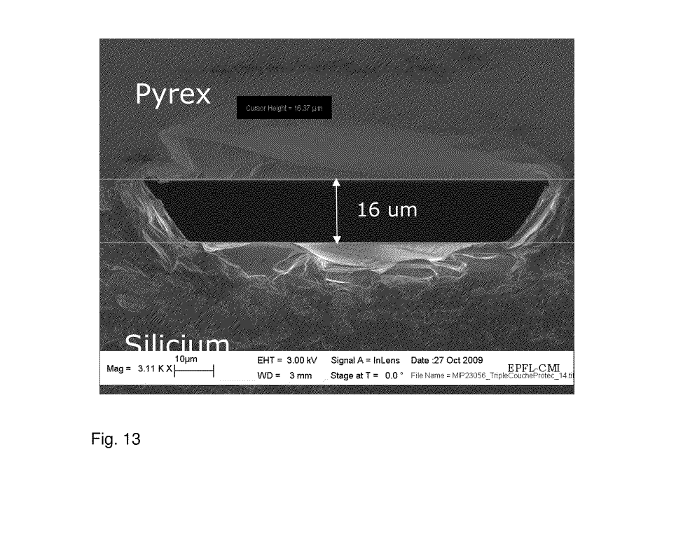

FIG. 13 shows that a design comprising a protective layer (a) of 100 nm Si₃N₄ on the silicon, a protective layer (b) of 200 nm of TiO2 (b) and a bonding layer (c) of 50 nm SiO₂ on the Pyrex wafer maintains a fluid resistance greater than or equal to the nominal value thereof over time when exposed to a pH 12 solution. In fact, the fluid resistance of the serpentine did not decrease for more than 140 days, unlike the designs used in the previous experiments. The slight increase in fluid resistance is rather attributed to items used in setup, comprising a filter upstream of the chip, which can become partly blocked over time and develops the trend observed in FIG. 12.

As shown in FIG. 14, after more than 140 days of incubation at pH 12, the channel forming the serpentine retains its nominal dimensions, thus suggesting that the assembly of protective layers as well as that of the bonding performed their function perfectly.

### REFERENCES

R1. S. Weichel, R. Reus S. Bouaidat, P. A. Rasmussen, O. Hansen, K. Birkelund, H. Dirac, Low-temperature anodic bonding to silicon nitride, in: Sensors and Actuators A, 82 (2000) 249-253

R2 A. Berthold, L. Nicola, P. M. Sarro, M. J. Vellekoop, Glass-to-glass anodic bonding with standard IC technology thin films as intermediate layers, in: Sensors and Actuators A, 82 (2000) 224-228

R3 K. M. Knowles, A. T. J. van Helvoort, Anodic bonding, in: International Materials Reviews, 51-5 (2006) 273-310

R4 T. N. H. Lee, D. H. Y. Lee, C. Y. N. Liaw, A. I. K. Lao, I. M. Hsing, Detailed characterization of anodic bonding process between glass and thin film-coated silicon substrates, in: Sensors and Actuators A, 86 (2000) 103-107

R5 D. J. Lee, Y. H. Lee, J. Jang, B. K. Ju, Glass-to-glass electrostatic bonding with intermediate amorphous silicon movie for vacuum packaging of microelectronics and its application, in: Sensors and Actuators A, 89 (2001) 43-48

R6 R. Legtenberg, S. Bouwstra, M. Elwenspoek, Low-temperature sensors for glass bonding applications using boron oxide thin films, in: J. Micromech. Microeng., 1(1991) 157-160

R7 A. Hanneborg, M. Nese, H. Jakobsen, R. Holm, Review: Silicon-to-thin film anodic bonding, in: J. Micromech. Microeng., 2(1992) 117-121

R8 M. Wiegand, M. Reiche, U. Gösele, K. Gutjahr, D. Stolze, R. Longwitz, E. Hiller, Wafer bonding of silicon wafers covered with various layers area, in: Sensors and Actuators A, 86 (2000) 91-95

R9 X. Du, K. Zhang, K. Holland, T. Tombler, M. Moskovits, Chemical corrosion protection of optical components using atomic layer deposition, in: Applied Optics, 48-33 (2009) 6470-6477

R10 J. W. Elam, D. Routkevitch, P. P. Mardilovich, S. M. George, Conformal coating on ultrahigh-aspect ratio nanopores of anodic alumina by atomic layer deposition, in: Chem. Mater., 15 (2003) 3507-3517

R11. T. Bork, F. Bianchi, Capillary fluidic chip for regulating drug flow rates of infusion pumps, European Patent EP2138198

R12. T. T. Veenstra et al., “Use of selective anodic bonding to create micropump chambers with virtually no dead volume”, J. Electrochem. Soc., 2000, 148 (2) p. G68-G72

1. A device comprising one wafer having a silicon surface and one wafer having a glass surface fixed to one another, the fixing zone formed between the wafers defining a multilayer structure comprising a first layer protecting against physical alteration of the material caused by an attack of the surface covering the silicon surface and a second layer protecting against physical alteration of the material caused by and attack of the surface covering the glass surface; said multilayer structure further comprising at least one additional layer enabling an anodic bond to be formed between the two protective layers; said device having at least one fluid path protected by said protective layers, adapted to temporarily contain a solution; said additional bonding layer having a thickness that is thin enough to form a capillary stop valve at the bond in the event of an attack on said additional bonding layer.

2. The device according to claim 1, wherein said additional bonding layer has a thickness less than 500 nm.

3. The device according to claim 2, wherein said additional bonding layer has a thickness less than 200 nm.

4. The device according to claim 3, wherein said additional bonding layer preferably has a thickness between 50 and 100 nm.

5. The device according to claim 1, wherein at least one of said protective layers is a conformal deposit.

6. The device according to claim 1, wherein said at least one additional bonding layer is a conformal deposit.

7. The device according to claim 1, wherein said attacks may be chemical, electrochemical, physical and/or mechanical.

8. The device according to claim 1, of the MEMS type, wherein the wafers are machinable.

9. The device according to claim 8, wherein the material constituting the protective layers which covers the glass and silicon surfaces is resistant to acid and/or basic pH.

10. The device according to claim 9, wherein said material constituting the protective layers can comprises for example titanium dioxide, titanium nitride or silicon nitride.

11. The device according to claim 10, wherein said bonding layer is only present on the protective layer that covers the glass wafer.

12. The device according to claim 11, of which the bonding layer is not resistant to a basic pH.

13. The device according to claim 12, of which the bonding layer consists of a material that undergoes a chemical transformation in the bond during anodic bonding that renders it resistant to basic solutions.

14. The device according to claim 13, of which the bonding layer consists of silicon dioxide.

15. The device according to claim 1, wherein said bonding layer is only present on the protective layer that covers the silicon wafer.

16. The device according to claim 1, wherein said bonding layer is also a protective layer.

17. The device according to claim 1, of which the bonding layer consists of silicon nitride of silicon.

18. The device according to claim 17, wherein the wafer with the glass surface is made from borosilicate such as Pyrex or from silicon.

19. The device according to claim 18, wherein the wafer with the silicon surface is made from silicon on an insulator or from glass.

20. The device according to claim 1, wherein said multilayer structure has a thickness less than 1 μm.

21. The device according to claim 1, wherein the protective and bonding layers are biocompatible.

22. The device according to claim 21, designed to be used as a medical system.

23. The device according to claim 22, designed to be used as an implantable medical system.

24. A method for manufacturing a MEMS type device comprising the steps of:
a) applying a layer protecting against chemical surface attack to at least one region of silicon on a primary surface of a first wafer,
b) applying a layer protecting against chemical surface attack to at least one region of glass on a primary surface of a second wafer,
c) adding a thin layer of a material that enables the creation of an anodic bond between the two protective layers while preventing infiltration by a solution into the bonding zone that defines the lateral extremities of a fluid path through which said solution passes.

25. The method according to claim 24, wherein at least one protective layer is deposited in such manner that the deposit is conformal.

26. The method according to claim 24, wherein said bonding layer is deposited in such manner that the deposit is conformal.

27. The method according to claim 24, wherein said wafers can be structured before and/or after steps a) and/or b).

28. The method according to claim 24, wherein steps a) and b) are preformed consecutively and/or simultaneously.

29. The method according to claim 24, wherein the two protective layers and the additional bonding layer are applied by one or a combination of the following techniques: Low Pressure Chemical Vapour Deposition (LPCVD), Plasma Enhanced Chemical Vapour Deposition (PECVD), Atomic Layer Deposition (ALD), oxidation, evaporation or sputtering.

30. A MEMS type device obtained by a method comprising the following steps:
a) applying a layer protecting against chemical surface attack to at least one region of silicon on a primary surface of a first wafer,
b) applying a layer protecting against chemical surface attack to at least one region of glass on a primary surface of a second wafer,
c) adding at least one thin layer of a material that enables the creation of an anodic bond between the two protective layers while preventing infiltration by a solution into the bonding zone that defines the lateral extremities of a fluid path through which said solution passes.

31. The device according to claim 30, wherein at least one protective layer is deposited in such manner that the deposit is conformal.

32. The device according to claim 30, wherein said bonding layer is deposited in such manner that the deposit is conformal.

33. The device according to claim 30, wherein said wafers can be structured before and/or after steps a) and/or b).

34. The device according to claim 30, wherein steps a) and b) are preformed consecutively and/or simultaneously.

35. The device according to claim 30, wherein the two protective layers and the additional bonding layer are applied by one or a combination of the following techniques: Low Pressure Chemical Vapour Deposition (LPCVD), Plasma Enhanced Chemical Vapour Deposition (PECVD), Atomic Layer Deposition (ALD), oxidation, evaporation or sputtering.
